(19) United States
(12) Patent Application Publication
(10) Pub. No.: US 2026/0068743 A1
(43) Pub. Date: Mar. 5, 2026

(54) HERMETIC PACKAGE WITH THIN LID TO REDUCE PACKAGE STRESS

(71) Applicant: Lumentum Operations LLC, San Jose, CA (US)

(72) Inventors: David DAVIES, Torquay (GB); Stuart CONLEY, Newton Abbot (GB); Jianghe YI, Shenzhen (CN); Kai LI, Shenzhen (CN); Paolo ZAGO, Milano (IT)

(21) Appl. No.: 18/945,227

(22) Filed: Nov. 12, 2024

Related U.S. Application Data
(60) Provisional application No. 63/687,510, filed on Aug. 27, 2024.

(51) Int. Cl. H01L 23/053; G02B 6/42; H01L 25/16

(52) U.S. Cl. CPC H01L 23/053; G02B 6/4259

(57) ABSTRACT

A hermetic optical package may include a package body comprising a surface and a plurality of walls. The surface and the plurality of walls may form a cavity. A smallest lateral dimension of the package body may be greater than approximately 7 millimeters (mm). The hermetic optical package may include one or more components mounted on the surface and within the cavity. The hermetic optical package may include a deformed package lid affixed to the plurality of walls and over the cavity. An average thickness of the deformed package lid may be less than approximately 150 micrometers (μm).

### CROSS-REFERENCE TO RELATED APPLICATION

This Patent Application claims priority to U.S. Provisional Ser. No. 63/687,510, filed on Aug. 27, 2024, and entitled “HERMETIC PACKAGE WITH THIN LID TO REDUCE PACKAGE STRESS.” The disclosure of the prior Application is considered part of and is incorporated by reference into this Patent Application.

### TECHNICAL FIELD

The present disclosure relates generally to a hermetic package and to a hermetic package with a thin lid to reduce package stress.

### BACKGROUND

Conventionally, a lid for a hermetic package with a large size (e.g., a package with a smallest lateral dimension greater than approximately 7 millimeters (mm)) is etched from a sheet of material that is relatively thick, such as a sheet of Kovar with a thickness of 0.254 mm. Such a conventional lid for a large hermetic package has a flange etched away around its edge so as to leave a flange with a thickness of approximately 100 micrometers (μm) around the edge of the lid. This flange facilitates resistance-welding seam-sealing of the lid to the package, which is used to provide a hermetic seal. Typically, an interior region (i.e., a region of the lid other than the flange) of the lid is left at the original thickness (e.g., 0.254 mm) in order to provide robustness of the lid and to limit lid deflection during other production processes.

### SUMMARY

In some implementations, a hermetic optical package includes a package body comprising a surface and a plurality of walls, the surface and the plurality of walls forming a cavity, wherein a smallest lateral dimension of the package body is greater than approximately 7 millimeters (mm); one or more components mounted on the surface and within the cavity; and a deformed package lid affixed to the plurality of walls and over the cavity, wherein an average thickness of the deformed package lid is less than approximately 150 micrometers (μm).

In some implementations, a hermetic package includes a package body comprising a surface and a plurality of walls, the surface and the plurality of walls forming a cavity, wherein a smallest lateral dimension of the package body is greater than approximately 7 mm; and a deformed package lid affixed to the plurality of walls and over the cavity, wherein an interior region of the deformed package lid has a thickness that is less than approximately 150 μm.

In some implementations, a hermetic package includes a package body comprising a surface and a plurality of walls, the surface and the plurality of walls forming a cavity, wherein a smaller lateral dimension of the package body is greater than approximately 7 mm, and wherein the surface of the package body has a peak-to-valley (PTV) deformation of less than 0.055% along a larger lateral dimension of the package body; and a deformed package lid affixed to the plurality of walls and over the cavity, wherein the deformed package lid has a PTV deformation of less than 0.050% along a larger lateral dimension of the deformed package lid.

### BRIEF DESCRIPTION OF THE DRAWINGS

FIG. 1 is a diagram illustrating inward pull that creates a bending moment on walls of a hermetic package.

FIGS. 2A and 2B illustrate and tabulate examples of package height, package wall thickness, package surface thickness, and lid or ringframe size for large and small packages having various characteristics, as described herein.

FIGS. 3A-3D are diagrams and a table associated with various examples of lid designs for a large hermetic package, as described herein.

FIG. 4 is a diagram illustrating an example environment in which a large hermetic package with a thin lid can be implemented.

FIG. 5 is a diagram illustrating a simplified block diagram of a transmitter receiver optical sub-assembly (TROSA) that can be housed in a large hermetic package described herein.

### DETAILED DESCRIPTION

The following detailed description of example implementations refers to the accompanying drawings. The same reference numbers in different drawings may identify the same or similar elements.

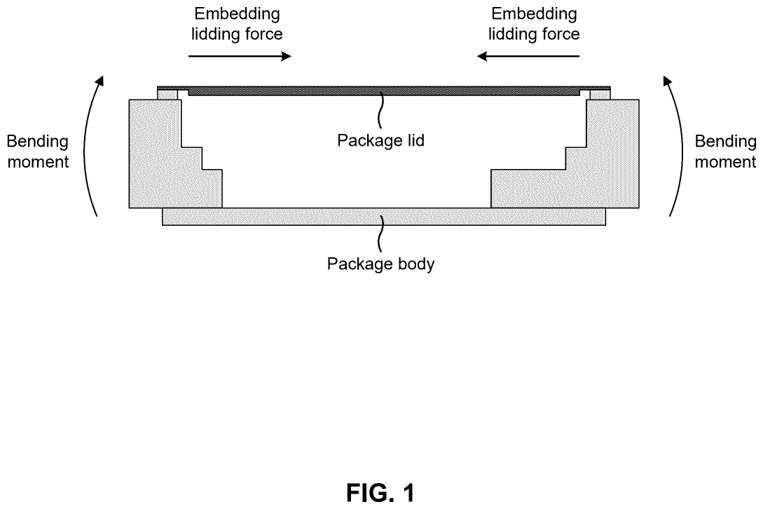

For some hermetic packages, a conventional thick lid can cause cracking of the package (e.g., a ceramic package) and/or bowing of a surface of the package (e.g., a package base). Such cracking and/or bowing is a byproduct of the welding of the lid, which occurs at a high temperature (e.g., approximately 1500 degrees Celsius (° C.) for Kovar). In practice, as the lid cools (e.g., to room temperature) after welding, the material of the lid shrinks and, therefore, pulls walls of the package inward. This inward pull creates a bending moment on the walls of the package, an example of which is illustrated in FIG. 1. The bending moment stresses the package and can cause the surface of the package to move outward. Package wall stress can result in package wall cracking, which compromises hermeticity (e.g., such that the package is non-hermetic). Additionally, because optical elements within the package are attached to the surface, bowing of the surface can adversely affect optical alignment inside the package, thereby reducing performance and reliability.

Some implementations described herein provide a large hermetic package with a thin lid. In some implementations, a hermetic package includes a package body including a surface and a plurality of walls, with the surface and the plurality of walls forming a cavity. In some implementations, a smallest lateral dimension of the package body is greater than approximately 7 mm. The hermetic package may further include a package lid affixed to the plurality of walls and over the cavity. In some implementations, an average thickness of the package lid is less than approximately 150 μm. Additionally, or alternatively, an interior region of the package lid may have a thickness that is less than approximately 150 μm. Additionally, or alternatively, the surface of the package body has a PTV deformation of less than 0.055% along a largest lateral dimension of the package body, and the package lid has a PTV deformation of less than 0.050% along a largest lateral dimension of the package lid, where the PTV deformations of the surface and the package lid are caused by a seam sealing process and thermal conditions associated with the seam sealing process and where the PTV deformations are compared against the package and lid as it was prior to the seam sealing process.

In some implementations, the thin lid reduces package stress (e.g., stress induced in walls of the package body by cooling after welding). A reduction of stress in the package serves to reduce a risk of the package cracking, and of bowing of a surface of the package. In some implementations, using a thin lid for a large hermetic package (e.g., using a flat lid with a thickness of 100 μm) reduces physical displacement and, therefore, reduces stress applied to walls of the package. This also reduces bowing of the surface of the package as a result of a lidding procedure. The reduction in physical displacement and stress in the package is achieved because, with a thin lid, the resultant force stretches the thinner lid comparatively more (e.g., as compared to an amount of stretch when a thick lid, such as a lid with a thickness of 254 μm, is used), meaning that comparatively less stress is imparted into the package. This results in a comparatively smaller displacement of the walls of the package and comparatively less bowing of the surface of the package. Notably, the use of the thin lid for a large hermetic package is contrary to the conventional theory that bowing, bending, and stretching of a lid is undesirable, and so lid thicknesses traditionally increases as package size increases. Additionally, thick lids have conventionally been used for large hermetic packages, rather than thin lids, due to durability concerns arising from the use of the comparatively thinner lids.

Further, a thin lid of a size needed for a large package has, conventionally, been difficult to manufacture, and therefore has been avoided. For example, handling of the thin material is difficult, which can lead to deformation of material and lower yield. Further, a lid layout in an etched sheet of material increases an amount of frame needed, which reduces lid count per sheet and, therefore, increases cost. Additionally, quality material for such thin lids (e.g., 0.1 mm thick Kovar) may not be readily available, meaning that sourcing quality material that remains flat throughout etching has been an issue.

Additionally, conventional manufacturing process considerations teach away from the use of a thin lid for a large package. For example, the use of a thin lid on a large package may require a reduction in a helium bomb pressure pre-leak test (e.g., from about 60+ pounds per square inch (psi) to approximately 30 psi). Such a reduction may be needed in order to limit a degree to which the lid is pushed inward due to the helium bomb pressure. Put simply, deflection of the lid under a constant pressure is inversely proportional to the lid thickness cubed, meaning that halving the thickness of the lid results in an eight-fold increase in deflection. In a particular example, reducing a thickness of the lid from 254 μm to 100 μm for the same package size leads to 16 times more deflection at the same pressure. Therefore, manufacturing or testing processes may need to be redesigned or modified in unconventional ways to accommodate for the thin lid.

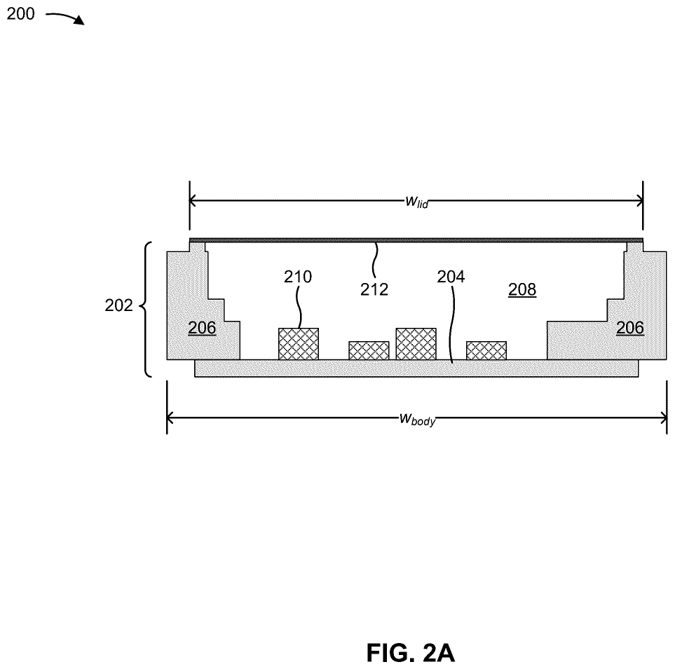

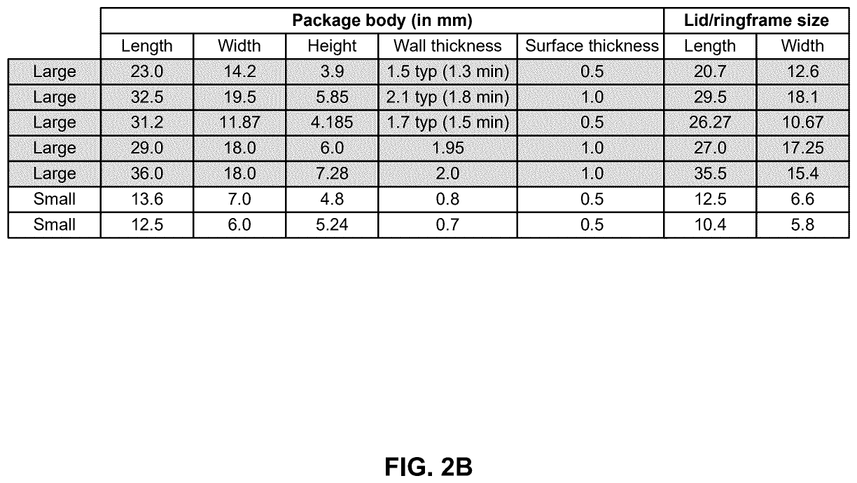

FIGS. 2A-2B are diagrams associated with a hermetic package comprising a thin lid as described herein. FIG. 2A is a diagram illustrating an example cross-section of a hermetic package 200. As shown, the hermetic package 200 comprises a package body 202 including a surface 204 and a plurality of walls 206, with the surface 204 and the plurality of walls 206 forming a cavity 208. As further shown, the hermetic package 200 may include one or more components 210 (e.g., one or more optical components, one or more components that form an optical sub-assembly, such as a TROSA, a coherent driver modulator (CDM), a receiver optical sub-assembly (ROSA), a transmitter optical sub-assembly (TOSA), an optical channel monitor (OCM), a pump laser, or the like) mounted on the surface 204 and within the cavity 208. As further shown, the hermetic package 200 includes a lid 212 that is affixed to the plurality of walls 206 and over the cavity 208. In some implementations, the lid 212 is affixed to the plurality of walls 206 so as to provide a hermetic seal for the hermetic package 200.

In some implementations, the hermetic package 200 is a large package. As used herein, a large package is a package with a smallest lateral dimension (e.g., a length or a width) that is greater than approximately 7 mm. Thus, in some implementations, the smallest lateral dimension of the package body 202 (e.g., a width identified as w_{body} in FIG. 2A) is greater than approximately 7 mm. For example, the smallest lateral dimension of the package body 202 may be at least approximately 10 mm. In some implementations, a largest lateral dimension of the package body 202 (e.g., a length of the package body 202, not shown in FIG. 2A) is greater than approximately 14 mm. For example, the largest lateral dimension of the package body 202 may be at least approximately 22 mm.

Dimensions of a package body 202 of various example hermetic packages 200 include: approximately 21 mm length by 13 mm width, approximately 29 mm length by approximately 18 mm width, approximately 26 mm length by approximately 11 mm width, approximately 24 mm length by 12 mm width, approximately 27 mm length by 17 mm width, and approximately 35 mm length by 15 mm width. FIG. 2B is a table illustrating further example dimensions of hermetic packages 200, as well as example dimensions of small hermetic packages (e.g., packages having a smallest lateral dimension that is less or equal to approximately 7 mm). The table shown in FIG. 2B further illustrates examples of package height, package wall thickness, package surface thickness, and lid/ringframe size for the example hermetic packages having dimensions shown in FIG. 2B.

In some implementations, the lid 212 may be a large thin lid. Thus, in some implementations, a smallest lateral dimension of the lid 212 (e.g., a width identified as w_{lid} in FIG. 2A) may be greater than approximately 7 mm. For example, the smallest lateral dimension of the lid 212 may be at least approximately 10 mm. In some implementations, a largest lateral dimension of the lid 212 (e.g., a length of the lid 212, not shown in FIG. 2A) is greater than approximately 10 mm. For example, the largest lateral dimension of the lid may be at least approximately 16 mm.

In some implementations, as described herein, the lid 212 may be a thin lid. A thin lid may be, for example, a lid having an average thickness that is less than approximately 150 μm. As another example, a thin lid may be a lid with one or more regions having a thickness that is less than approximately 150 μm. In one example, the thickness of the lid 212 may be approximately 100 μm across one or more regions of the lid that comprise at least 50% of an area of the lid 212. In some implementations, the lid 212 may have a uniform thickness. For example, the thickness across the width of the lid 212 and the length of the lid 212 may be approximately 100 μm, approximately 127 μm, or another thickness that is less than approximately 150 μm.

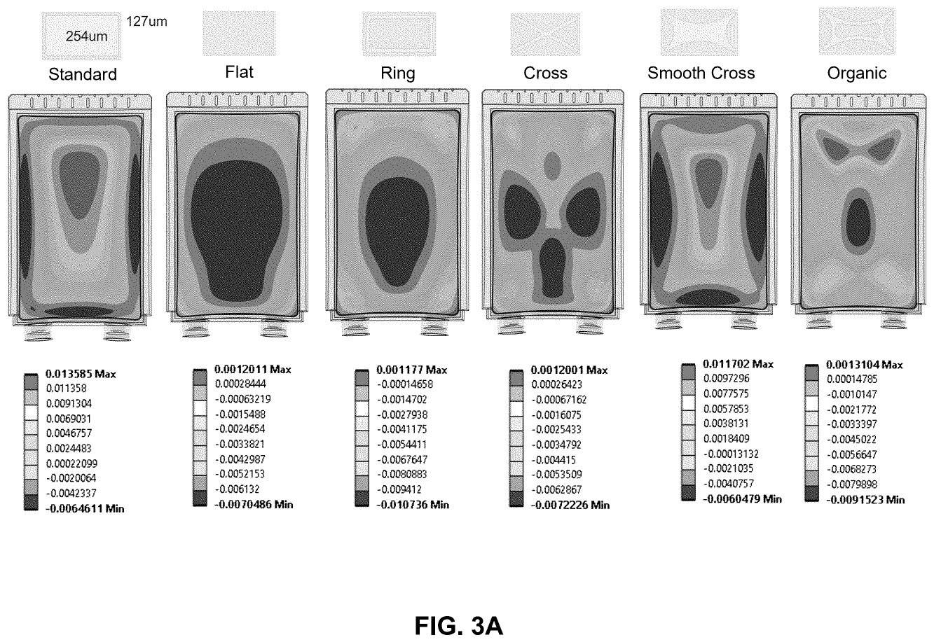

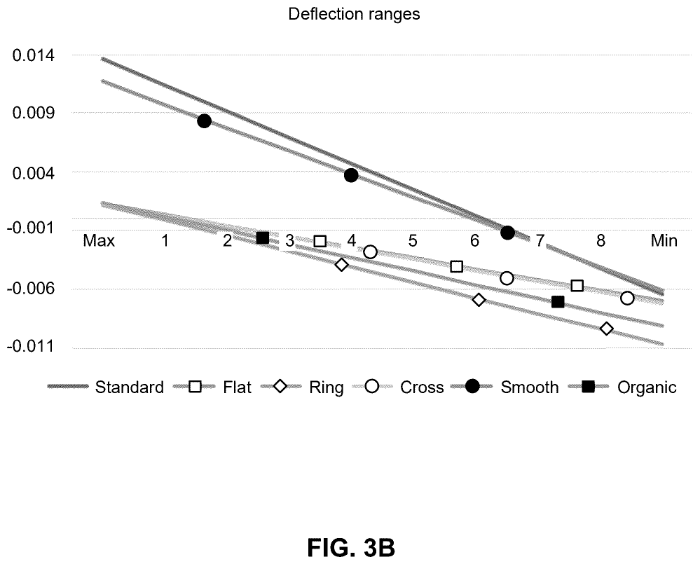

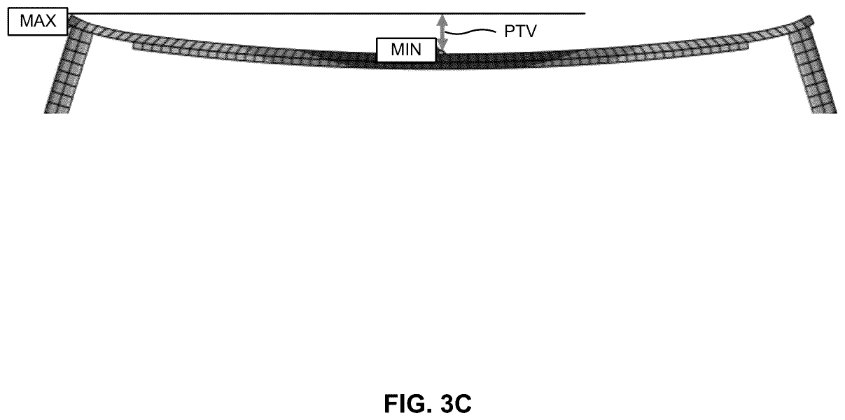

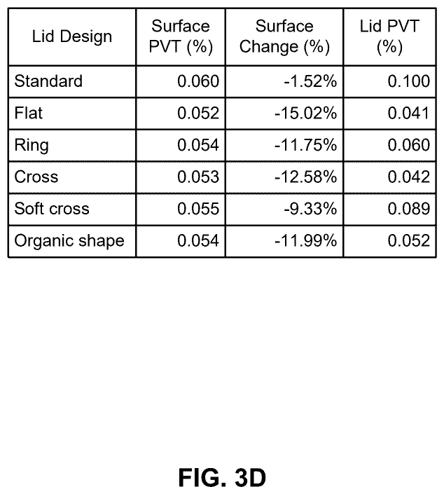

FIGS. 3A-3D are diagrams associated with various example designs of the lid 212 of the hermetic package 200. The lids 212 in the examples associated with FIGS. 3A-3D have a length of approximately 20.5 mm and a width of approximately 12.5 mm. FIG. 3A illustrates simulated lid deformations (in mm) for a conventional thick lid (i.e., a “Standard” 254 μm thick lid with a 100 μm thinned edge edge), a flat lid 212 (e.g., a lid 212 having a uniform thickness of 127 μm), a ring lid 212 (e.g., a lid 212 having a ring-shaped region with a thickness of 254 μm, while other regions of the lid 212 have a 100 μm thickness), a cross lid 212 (e.g., a lid 212 having a cross-shaped region with a thickness of 254 μm, while other regions of the lid 212 have a 100 μm thickness), a smooth-cross lid 212 (e.g., a lid 212 having a smooth-cross-shaped region with a thickness of 254 μm, while other regions of the lid 212 have a 100 μm thickness), and an organic lid 212 (e.g., a lid 212 having an organic-shaped region with a thickness of 254 μm, while other regions of the lid 212 have a 100 μm thickness). As can be seen in FIG. 3A, deformation is reduced for each of the designs for the thin lid 212 as compared to the conventional thick lid. FIG. 3B illustrates the deflection ranges for the conventional thick lid and the various thin lids 212 shown in FIG. 3A.

In some implementations, the lid 212 reduces stress induced in the plurality of walls 206 of the package body 202 (e.g., stress induced by cooling after welding of the lid 212 to the plurality of walls 206). As noted above, a reduction of stress in the package body 202 serves to reduce a risk of package cracking and bowing of the surface 204 of the hermetic package 200. In some implementations, using a thin lid 212 for a large hermetic package 200 (e.g., using a lid 212 with a uniform thickness of 100 μm) reduces physical displacement and, therefore, reduces stress applied to the walls 206 of the hermetic package 200. This also reduces bowing of the surface 204 of the hermetic package 200 over lidding. The reduction in physical displacement and stress in the hermetic package 200 is achieved because, with a thin lid 212, the resultant force stretches the thinner lid 212 comparatively more (e.g., as compared to an amount of stretch for a conventional thick lid), meaning that comparatively less stress is imparted into the hermetic package 200. This results in a comparatively smaller displacement of the walls 206 of the hermetic package 200 and comparatively less bowing of the surface 204 of the hermetic package 200. Notably, the use of the thin lid 212 for a large hermetic package 200 is contrary to the conventional theory that bowing, bending, and stretching of a lid is undesirable, and so lid thicknesses traditionally increase as package size increases.

In some implementations, after cooling of the lid 212 after affixing (e.g., seam sealing) to the package body 202, the surface 204 of the package body 202 has a peak-to-valley (PTV) deformation of less than 0.055% along the largest lateral dimension of the package body 202 and the lid 212 has a PTV deformation of less than 0.050% along the largest lateral dimension of the lid 212. As used herein, PTV as a measurement of the deformation of an element of the hermetic package 200 (e.g., the lid 212 or the surface 204) caused by loading conditions associated with a process for affixing the lid 212 to the package body 202 (e.g., a seam sealing process). The loading conditions may include, for example, a pressure load (e.g., a seam sealing pressure) applied to the hermetic package 200 during the process, a thermal load applied during the process (e.g., local heating of elements of the hermetic package 200 during the seam sealing process to create a bond between the lid 212 and the package body 202). In some implementations, the thermal load may be taken into account as a single step (e.g., an average temperature distribution on the lid 212 when the lid 212 is affixed to the package body 202, and is then cooled to room temperature, which induces thermal stress) or as multiple steps (e.g., with consideration of all process steps and a transient thermal load of a tool running along edges of the hermetic package 200). The PTV is a distance between a highest point (e.g., a maximum height) and a lowest point (e.g., a minimum height) in a vertical direction (e.g., along a height of the hermetic package 200). FIG. 3C illustrates an example of a deformed lid 212, where the maximum and minimum height of the deformed lid 212, as well as the associated PTV, are indicated. FIG. 3D is a table illustrating example PTVs for the conventional thick lid and the various thin lid designs described above with respect to FIGS. 3A-3B.

Some hermetic packages 200 (e.g., a TROSA package, CDM package, a ROSA package, a TOSA package, an OCM package, a pump laser package, or the like) have significant spatial limitations, and so thicknesses of the plurality of walls 206 of the hermetic package 200 and the surface 204 of the hermetic package 200 need to be reduced as much as possible (e.g., to maximize usable space within the cavity 208 of the hermetic package 200). However, reducing a thickness of the walls 206 and the surface 204, in effect, increases fragility of the hermetic package 200 such that the hermetic package 200 is more sensitive to applied loads. Further, optical design in a package such as a TROSA commonly includes transverse free space beams across the hermetic package 200 (e.g., a width of the hermetic package 200) with optical components (e.g., reflectors, lenses, mirrors, etc.) at each end, meaning that (optical) components 210 mounted on the surface 204 and beam alignment within the package can be sensitive to package bending. As noted above, the use of a thin lid 212 on a large hermetic package 200 reduces stress applied to the hermetic package 200. Therefore, the use of the thin lid 212 can serve to mitigate an impact of reduction in thickness of the walls 206 or the surface 204 of the hermetic package 200, thereby enabling usable space within the hermetic package 200 to be maximized.

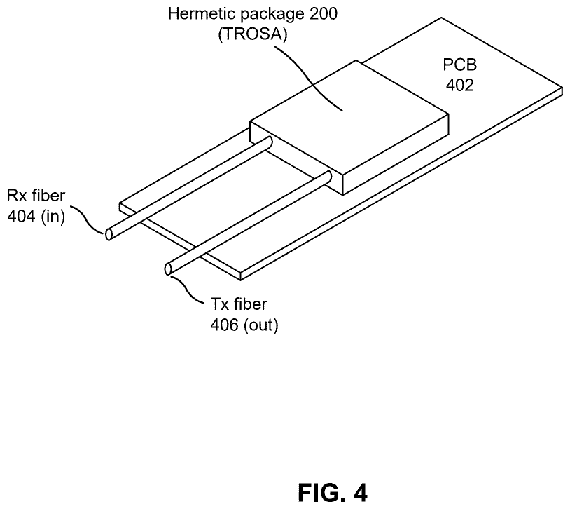

FIG. 4 is a diagram illustrating an example environment in which the large hermetic package 200 with the thin lid 212 can be implemented. In the example shown in FIG. 4, the hermetic package 200 is a TROSA package (herein referred to as TROSA package 200). As shown in FIG. 4, in some such implementations, the TROSA package is mounted on a printed circuit board (PCB) 402 such that the lid 212 of the TROSA package 200 is affixed to the PCB 402 (e.g., the TROSA package 200 may be mounted on the PCB 402 in a “flipped” position). As further shown, a receiver (Rx) fiber 404 and a transmitter (Tx) fiber 406 may enable optical signals to be received at and transmitted from the TROSA package 200, respectively. Notably, the mounting of the TROSA package 200 on the PCB 402 can in some implementations reduce fragility of the TROSA package 200 (e.g., such that durability of the TROSA package 200 with the thin lid 212 can be increased). In some implementations, the TROSA package 200, the PCB 402, the Rx fiber 404, and the Tx fiber 406 may be housed in a TROSA module (e.g., a housing, not shown) along with one or more other components (e.g., a socket, a PCB thermal pad, a TROSA thermal pad, a digital signal processor (DSP), a DSP thermal pad, or the like).

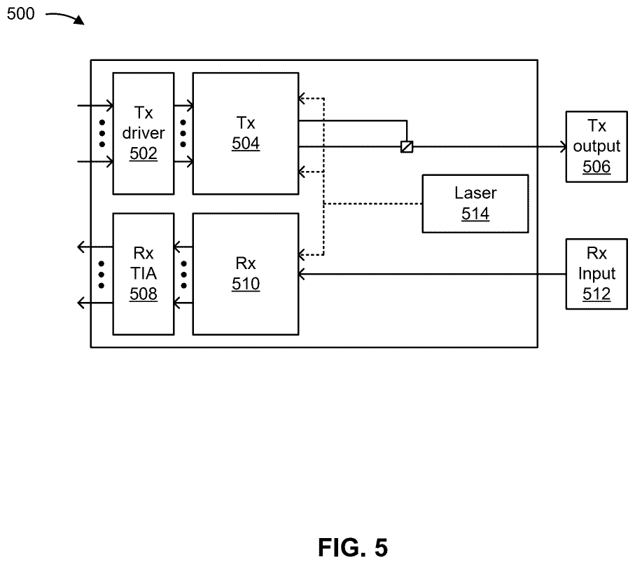

FIG. 5 is a diagram illustrating a simplified block diagram of a TROSA 500 (e.g., a TROSA housed in the TROSA package 200 illustrated in FIG. 4). As shown in FIG. 5, the TROSA 500 may include a Tx driver 502, a Tx chip 504 (e.g., a Tx photonic integrated circuit (PIC)), a Tx output 506, an Rx transimpedance amplifier (TIA) 508, an Rx chip 510 (e.g., an Rx PIC), an Rx input 512, or a laser 514 (e.g., a light source). In some implementations, such a TROSA 500 may be included in a large hermetic package 200 with a thin lid 212 as described herein.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A hermetic optical package, comprising:
a package body comprising a surface and a plurality of walls, the surface and the plurality of walls forming a cavity,
wherein a smallest lateral dimension of the package body is greater than approximately 7 millimeters (mm);
one or more components mounted on the surface and within the cavity; and
a deformed package lid affixed to the plurality of walls and over the cavity,
wherein an average thickness of the deformed package lid is less than approximately 150 micrometers (μm).

2. The hermetic optical package of claim 1, wherein the smallest lateral dimension of the package body is at least approximately 10 mm.

3. The hermetic optical package of claim 1, wherein a largest lateral dimension of the package body is greater than approximately 14 mm.

4. The hermetic optical package of claim 1, wherein a largest lateral dimension of the package body is at least approximately 22 mm.

5. The hermetic optical package of claim 1, wherein a smallest lateral dimension of the deformed package lid is greater than approximately 7 mm.

6. The hermetic optical package of claim 1, wherein a smallest lateral dimension of the deformed package lid is at least approximately 10 mm.

7. The hermetic optical package of claim 1, wherein a largest lateral dimension of the deformed package lid is greater than approximately 10 mm.

8. The hermetic optical package of claim 1, wherein a largest lateral dimension of the deformed package lid is at least approximately 16 mm.

9. The hermetic optical package of claim 1, wherein the thickness of the deformed package lid is approximately 100 μm across at least 50% of an area of the deformed package lid.

10. The hermetic optical package of claim 1, wherein the thickness of the deformed package lid is uniform.

11. The hermetic optical package of claim 1, wherein the deformed package lid comprises a cross-shaped region in which a thickness of the deformed package lid is greater than a thickness of the deformed package lid in regions other than the cross-shaped region.

12. The hermetic optical package of claim 1, wherein the hermetic optical package is one of a transmitter receiver optical sub-assembly (TROSA) package, a coherent driver modulator (CDM) package, a receiver optical sub-assembly (ROSA) package, a transmitter optical sub-assembly (TOSA) package, an optical channel monitor (OCM) package, or a pump laser package.

13. The hermetic optical package of claim 1, wherein the one or more components comprise at least one of a transmitter (Tx) driver, a Tx chip, a Tx output, a receiver (Rx) transimpedance amplifier (TIA), an Rx chip, an Rx input, or a laser.

14. The hermetic optical package of claim 1, wherein an interior region of the deformed package lid has a thickness that is less than approximately 150 μm.

15. The hermetic optical package of claim 1, wherein the surface of the package body has a peak-to-valley (PTV) deformation of less than 0.055% along a largest lateral dimension of the package body and the deformed package lid has a PTV deformation of less than 0.050% along a largest lateral dimension of the deformed package lid.

16. The hermetic optical package of claim 1, wherein the deformed package lid is affixed to the plurality of walls by a seam seal.

17. The hermetic optical package of claim 1, wherein deformation of the deformed package is associated with one or more loading conditions associated with affixing the deformed package lid to the plurality of walls

18. A hermetic package, comprising:
a package body comprising a surface and a plurality of walls, the surface and the plurality of walls forming a cavity,
wherein a smallest lateral dimension of the package body is greater than approximately 7 millimeters (mm); and
a deformed package lid affixed to the plurality of walls and over the cavity,
wherein an interior region of the deformed package lid has a thickness that is less than approximately 150 micrometers (μm).

19. The hermetic package of claim 18, wherein the surface of the package body has a peak-to-valley (PTV) deformation of less than 0.055% along a largest lateral dimension of the package body and the deformed package lid has a PTV deformation of less than 0.050% along a largest lateral dimension of the deformed package lid.

20. A hermetic package, comprising:
a package body comprising a surface and a plurality of walls, the surface and the plurality of walls forming a cavity,
wherein a smaller lateral dimension of the package body is greater than approximately 7 millimeters (mm), and
wherein the surface of the package body has a peak-to-valley (PTV) deformation of less than 0.055% along a larger lateral dimension of the package body; and
a deformed package lid affixed to the plurality of walls and over the cavity,
wherein the deformed package lid has a PTV deformation of less than 0.050% along a larger lateral dimension of the deformed package lid.
